(19) United States
(12) Patent Application Publication
(10) Pub. No.: US 2001/0042895 A1
(43) Pub. Date: Nov. 22, 2001

(54) Method of forming a photo sensor in a photo diode

(76) Inventor: Jui-Hsiang Pan, Hsin-Chu City (TW)

Correspondence Address: WINSTON HSU, 5F, No. 389, Fu-Ho Road, Tung-Ho City, Taipei Hsien, 234, TW

(21) Appl. No.: 09/871,665

(22) Filed: Jun. 4, 2001

Related U.S. Application Data
(62) Division of application No. 09/449,534, filed on Nov. 29, 1999.

(51) Int. Cl. H01L 27/14; H01L 31/00

(52) U.S. Cl. 257/431

(57) ABSTRACT

A semiconductor wafer is provided. The semiconductor wafer comprises a silicon substrate containing first-type dopants, a well of first-type dopants positioned in a predetermined region on the substrate, and a photo diode positioned on the semiconductor wafer. The photo diode comprises an active region positioned on the surface of the well. The active region is used to form a MOS transistor of second-type dopants. An insulation layer is positioned on the surface of the substrate and surrounds a predetermined photo sensor, the photo sensor being positioned beside the well. Following this, a first ion implantation process is performed to form a first doped region of second-type dopants on the surface of the photo sensor. A second ion implantation process is then performed to form a second doped region of second-type dopants inside the photo sensor. The second doped region is positioned under the first doped region, and the dopant density of the second doped region is less than that of the first doped region. Hence, the second doped region functions to reduce the electrical field around the first doped region to reduce leakage current.

### BACKGROUND OF THE INVENTION

1. Field of the Invention

The present invention relates to a method of forming a photo sensor in a photo diode on a semiconductor wafer.

2. Description of the Prior Art

The photo diode is a semiconductor device comprising a photo-conductivity cell and a junction diode, and is commonly used in photo-electronic products, such as cameras and the photo sensors of scanners. The current in the photo diode induced by light represents a signal, whereas the current present in the device in the absence of light represents noise. The photo diode processes signal data by using the value of the signal-to-noise ratio. In the semiconductor industry, it is often desired to increase the current induced by light in the photo diode so as to increase the signal-to-noise ratio, and hence to enhance the contrast of the signal. The sensitivity of the photo diode is thereby increased and the quality of the photo diode is improved.

Please refer to FIG. 1. FIG. 1 is a cross-sectional diagram of the structure of a prior art photo diode 10. A prior art photo sensor 20 in the photo diode 10 is positioned on the semiconductor wafer 11. The semiconductor wafer 11 comprises a silicon substrate 12 and a p-well 14 positioned on the silicon substrate 12. The photo diode 10 comprises an n-type metal oxide semiconductor (NMOS) transistor 16 positioned on the surface of the p-well 14, and a photo sensor 20 formed on the surface of the p-well 14 that is electrically connected to the NMOS transistor. The semiconductor wafer 11 also comprises a field oxide layer 18 positioned on the surface of the p-well 14 that surrounds the photo sensor 20. The field oxide layer 18 acts as a dielectric insulating material to prevent secondary short circuiting due to contact between the photo sensor and other units.

In the formation of the prior art photo sensor 20 in the photo diode 10, a high dosage of arsenic (As) atoms is used as the major dopant in an ion implantation process. This ion implantation process is performed to form an n-type doped region 22 on the surface of the p-well 14. A depletion region 24 for detecting the leakage current is formed along the PN junction between the doped region 22 and the adjacent p-type well 14. In FIG. 1, the area marked with slanting lines illustrates the depletion region 24.

The doped region 22 formed by the high dosage ion implantation process, and the p-well 14 that also has a high dopant density, will both result in a narrower width of the depletion region 24, and will also decrease the real active region of the photo sensor 20. Therefore, the light-induced current sensed by the depletion region 24 is reduced. Also, the interface of the doped region 22 and the p-well 14 under the field oxide layer 18 induces additional noise. As a result, the signal-to-noise ratio is lowered and the sensitivity of the photo sensor 20 is reduced.

### SUMMARY OF THE INVENTION

It is therefore a primary objective of the present invention to provide a method of forming a photo sensor in a photo diode to solve the above mentioned problems.

According to the claimed invention, a semiconductor wafer is provided. The surface of the semiconductor wafer comprises a silicon substrate, a p-well positioned in a predetermined region on the substrate, and a photo diode positioned on the semiconductor wafer. The photo diode comprises an NMOS transistor positioned on the surface of the p-well serving as a reset MOS transistor of the photo diode, a photo sensor positioned beside the p-well and electrically connected with the NMOS transistor, a field oxide layer surrounding the photo sensor and acting as an insulation layer, and a channel stop positioned under the field oxide layer. A first ion implantation process is performed to form a first n-type doped region on the surface of the photo sensor by using arsenic atoms as dopants. The dosage and the energy for the first ion implantation process is around 10¹⁶ cm⁻³ and less than 80 Kev, respectively. Then a second ion implantation process is performed on the photo sensor area to form a second n-type doped region under the first n-type doped region by using phosphorus atoms as dopants. The dosage and the energy for the second ion implantation process is less than 10¹³ cm⁻³ and larger than 200 Kev, respectively. The dopant density of the second n-type doped region is lower than the dopant density of the first n-type doped region. The periphery of the second n-type doped region is in contact with the channel stop, and a portion of the second doped region is at least partially under it. As a result, the second n-type doped region functions to reduce the electrical field around the first n-type doped region so as to reduce the leakage current. In addition, dopants in the second n-type doped region will interact with the substrate to form a depletion layer so as to enhance the sensitivity of the photo diode.

It is an advantage of the present invention that the dosage density of the p-type and n-type dopants is doubly reduced. That is, the prior art p-well with a high dopant density is replaced by the p-type silicon substrate with a lower dopant density, and a second n-type doped region with a low dopant density that is formed under the first n-type doped region. Hence, the electrical field around the pn-junction and the resulting noise can both be reduced so as to increase the width of the depletion region in the photo sensor and improve the sensitivity of the photo diode.

These and other objectives of the present invention will no doubt become obvious to those of ordinary skill in the art after reading the following detailed description of the preferred embodiment which is illustrated in the various figures and drawings.

### BRIEF DESCRIPTION OF THE DRAWINGS

FIG. 1 is a cross-sectional diagram of the structure of the prior art photo diode.

FIG. 2 is a cross-sectional diagram of the structure of the present invention photo diode.

FIG. 3 to FIG. 7 are cross-sectional diagrams of the process of forming the photo sensor in the photo diode according to the present invention.

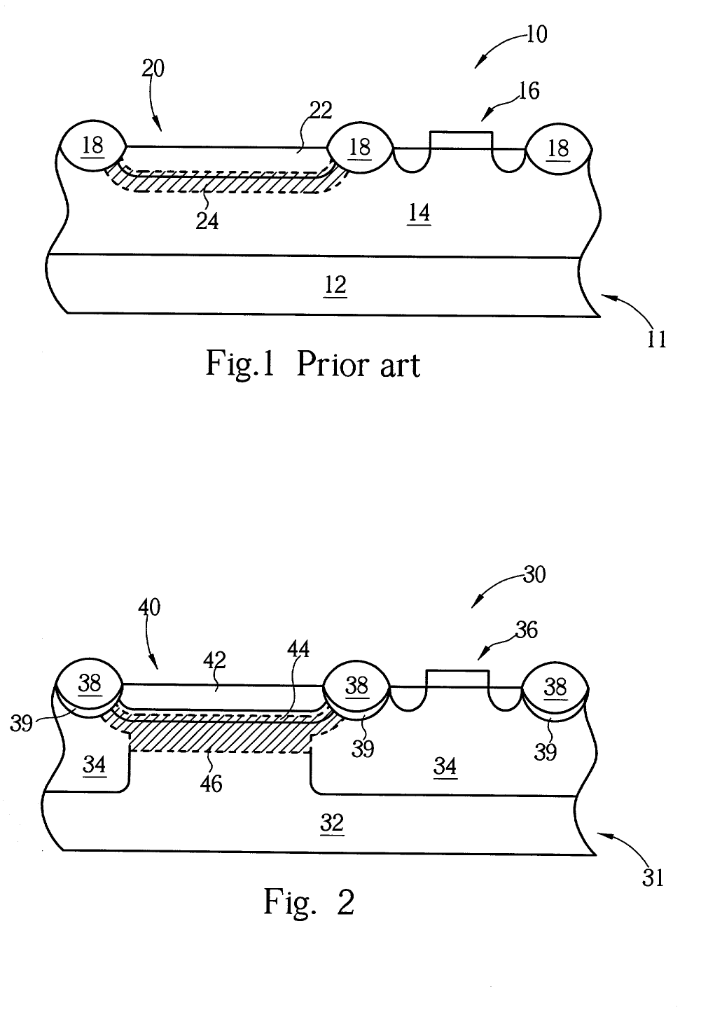

### DETAILED DESCRIPTION OF THE PREFERRED EMBODIMENT

Please refer to FIG. 2. FIG. 2 is a cross-sectional diagram of the structure of a present invention photo diode 30. The present invention provides the method for forming a photo sensor 40 in a photo diode 30. In the following description, we shall consider a semiconductor wafer which comprises a p-type silicon substrate. A semiconductor wafer 31 comprises a p-type silicon substrate 32, and a p-well 34 positioned on a predetermined area of the p-type silicon substrate 32. The photo diode 30 comprises an NMOS transistor 36 positioned on the surface of the p-well 34, a photo sensor 40 positioned beside the p-well 34 and electrically connected to the NMOS transistor 36, a field oxide layer 38 positioned on the surface of the p-well 34 and surrounding the photo sensor 40, and a channel stop 39 positioned under the field oxide layer 38. The NMOS transistor 36 functions as the reset MOS transistor of the photo diode to zero the photo sensor 40. The field oxide layer 38 acts as a dielectric insulating material to prevent short circuiting between the photo sensor 40 and other units. The channel stop 39 is used to prevent inversion of the field oxide layer 38 that could result in short circuiting.

The present invention photo sensor 40 comprises an n-type doped region 42 positioned on the surface of the photo sensor 40, and an n-type doped region 44 positioned under the n-type doped region 42. The periphery of the n-type doped region 44 is in contact with the channel stop 39, and a portion of the n-type doped region 44 is at least partially under the channel stop 39. The dopants of the n-type doped regions 42 and 44 are arsenic atoms and phosphorus atoms, respectively.

The dopant density of the n-type doped region 44 is lower than that of the n-type doped region 42. The n-type doped region 44 reduces the electrical field around the n-type doped region 42 and thereby reduces the noise associated with the field. In addition, a depletion region 46 for detecting leakage current is formed along the PN junction between the n-type doped region 44 and the adjacent silicon substrate 32. In FIG. 2, the area marked with slanting lines illustrates the depletion region 46.

The above mentioned example is given with a p-type silicon substrate 32. If the silicon substrate is n-type, then the well positioned on it would be an n-well and the two doped regions of the photo sensor would be p-type. In this case, the dopants in the doped regions 42 and 44 would be BF₂⁺ and boron (B) , respectively.

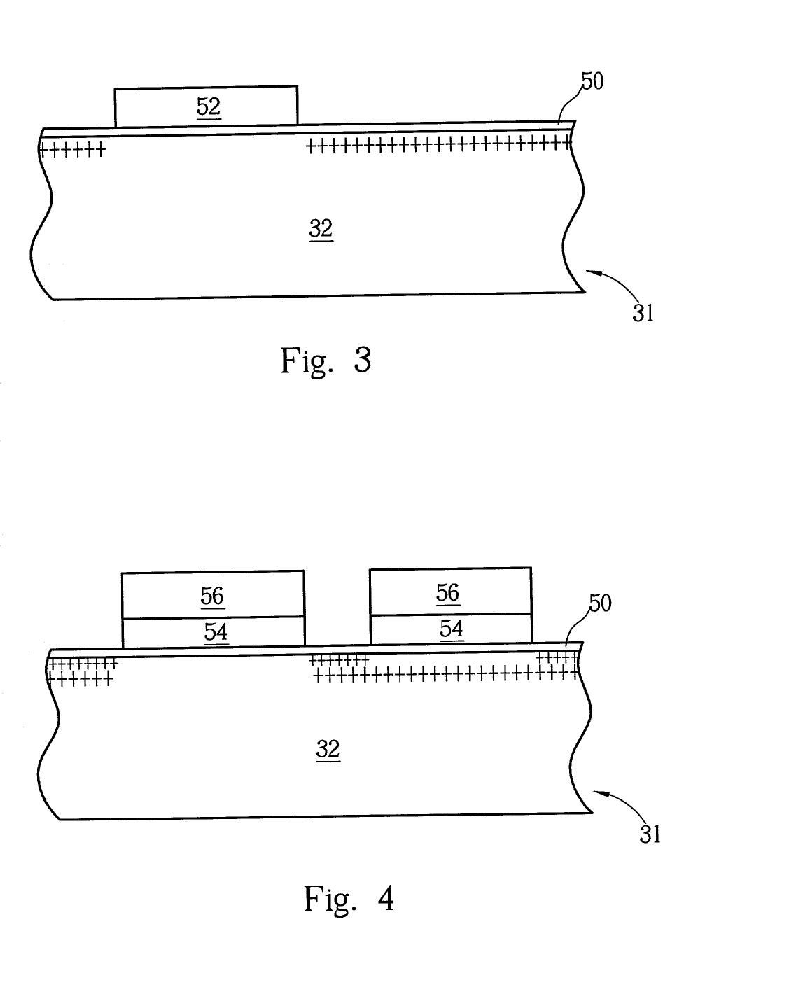

Please refer to FIG. 3 to FIG. 7. FIG. 3 to FIG. 7 are cross-sectional diagrams of the process of forming the photo sensor 40 in the photo diode 30 according to the present invention. The following description considers the case of a semiconductor wafer which comprises a p-type silicon substrate. As shown in FIG. 3, in the present invention the semiconductor wafer 31 with a p-type substrate 32 is placed into a thermal oxidation furnace after a cleaning process has been performed. A thermal oxidation process is performed to form a silicon oxide layer 50 that can be hundreds of angstroms thick on the surface of the silicon substrate. The silicon oxide layer 50 acts as a sacrificial oxide layer in a subsequent ion implantation process; it enhances the scattering of ions so as to prevent channeling. A photoresist layer is coated over the surface of the silicon substrate 32, and the predetermined photo sensor 40 area is defined to remove the photoresist layer in the other regions, leaving only the partial photoresist layer 52. An ion implantation process using boron (B) as the dopant is then performed on the areas not covered by the photoresist layer 52. The energy during the ion implantation process is around 180 KeV.

The photoresist layer 52 is stripped. A thin film deposition process is performed using a chemical vapor deposition method. A silicon nitride layer 54, around 1000 to 2000 angstroms thick, is thus formed on the silicon oxide layer 50. A lithographic and etching process is then performed. A photoresist layer 56 is coated onto the surface of the silicon nitride layer 54. A lithographic process is used to remove a portion of the photoresist layer 56 from a predetermined region. A dry etching process is then performed to remove the silicon nitride layer 54 that isn't covered by the photoresist layer 56. The residual silicon nitride layer 54 on the wafer 31 is used as the mask of a local oxidation (LOCOS) process to define the active area, as shown in FIG. 4. An ion implantation process is performed for the formation of the later channel stop 39 by implanting group IIIA ions, such as boron (B) ions.

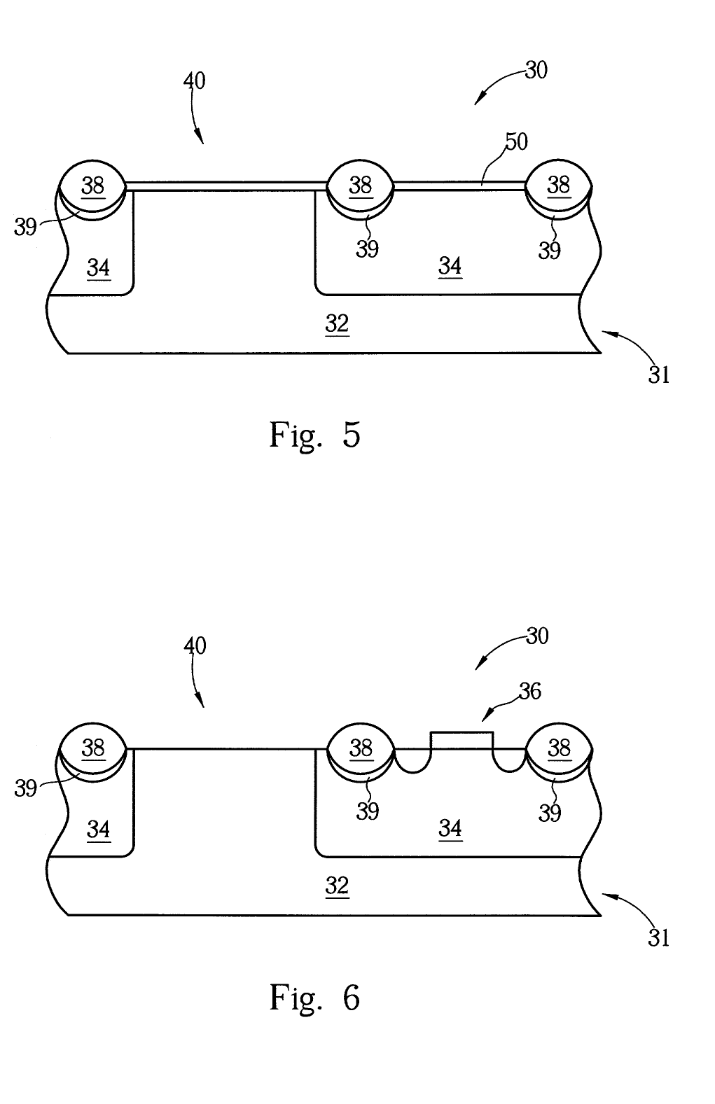

After stripping the photoresist layer 56, the formation of p-well 34, field oxide layer 38 and channel stop 39, as shown in FIG. 5, is performed. The semiconductor wafer 31 is placed into a thermal oxidation furnace after a cleaning process. The field oxide layer 38 is grown using a wet oxidation process and simultaneously the boron ions are driven in the silicon substrate 32 to form the channel stop 39 under the field oxide layer 38. This step takes advantage of silicon nitride, which prevents diffusion of oxygen and water, to form the field oxide layer 38. A wet etching process follows to strip the silicon nitride layer 54. Heated phosphoric acid is used as the etching solution.

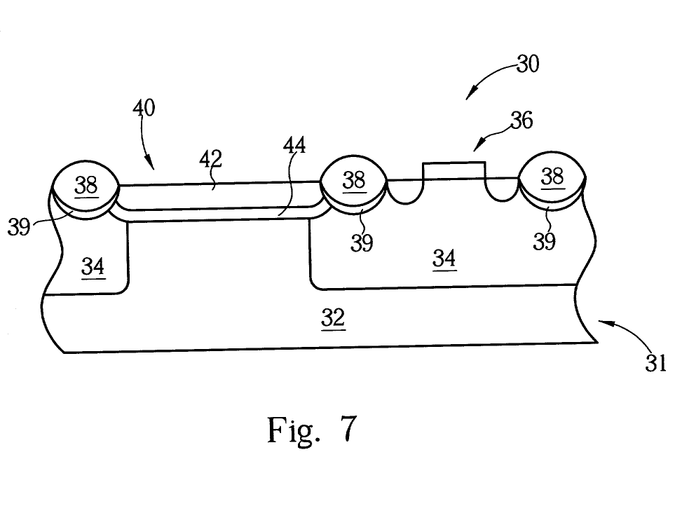

The silicon oxide layer 50 is stripped completely. Ion implantation processes, thin film deposition processes and cleaning processes are performed on the surface of the wafer 31 to form an NMOS transistor 36, as shown in FIG. 6. As shown in FIG. 7, an ion implantation process is performed to form an n-type doped region 42 on the surface of the photo sensor 40, using arsenic (As) atoms as the doping ions. The dosage and the energy during the ion implantation process are around 10¹⁶ cm⁻³ and less than 80 KeV, respectively. Another ion implantation process is then performed to form the n-type doped region 44 under the n-type doped region 42, using phosphorus (P) atoms as the doping ions. The dosage and the energy in the ion implantation process are less than 10¹³ cm⁻³ and higher than 200 KeV, respectively.

Although in the above description the NMOS transistor is formed before the photo sensor 40, the processing order of the two devices could be swapped, or they could be formed together simultaneously. In addition, the order of the ion implantation processes for the n-type doped regions 42 and 44 could also be exchanged.

In the present invention photo sensor 40 of the photo diode 30, the dopant density in the n-type doped region 44 is less than 10¹³ cm⁻³, so the electrical field around then-type doped region 42 is reduced, and the associated noise is also reduced, especially in the region under the field oxide layer 38. In addition, the phosphorus dopants in the n-type region 44 interact with the p-type substrate to form a wider depletion region 46 so as to expand the real active region and enhance the sensitivity of the photo diode. Consequently, the present invention enhances the magnitude of the light-induced current and increases the signal-to-noise ratio of the photo diode.

In contrast to the prior art photo sensor, the photo sensor 40 according to the present invention doubly reduces the dopant density of the p-type and n-type semiconductors. The prior art p-well 14 is replaced by the p-type silicon substrate 32 whose dopant density is less than the p-well 14. The n-type doped region 44 with a low dopant density is added under the n-type doped region 42. Consequently, the electrical field around the pn-junction is reduced and the noise associated with the field is also reduced. The present invention increases the width of the depletion region and promotes the sensitivity of the photo diode.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of forming a photo sensor in a photo diode on a semiconductor wafer, the surface of the semiconductor wafer comprising a silicon substrate containing first-type dopants, a well of first-type dopants positioned in a predetermined region on the substrate, a photo diode positioned on the semiconductor wafer and comprising an active region positioned on the surface of the well, the active region being used to form a MOS transistor of second-type dopants, and an insulation layer positioned on the surface of the substrate surrounding a predetermined photo sensor, the photo sensor positioned beside the well, the method comprising:
performing a first ion implantation process to form a first doped region of second-type dopants on the surface of the photo sensor; and
performing a second ion implantation process to form a second doped region of second-type dopants inside the photo sensor;
wherein the second doped region is positioned under the first doped region, the dopant density of the second doped region is less than that of the first doped region, and the second doped region functions to reduce the electrical field around the first doped region so as to reduce leakage current.

2. The photo sensor of claim 1 wherein the first-type dopants are either n-type or p-type, and the second-type dopants are either n-type or p-type but different from the first-type.

3. The method of claim 2 wherein the n-type dopants in the first ion implantation process are arsenic (As) atoms, the ion implantation energy is less than 80 KeV and the dopant density is around 10¹⁶ cm⁻³.

4. The method of claim 2 wherein the n-type dopants in the second ion implantation process are phosphorus (P) atoms, the ion implantation energy is larger than 200 KeV and the dopant density is less than 10¹³ cm⁻³.

5. The photo sensor of claim 2 wherein the dopants in the second doped region interact with the substrate to form a depletion region so as to enhance the sensitivity of the photo diode.
